(19) United States
(12) Patent Application Publication
(10) Pub. No.: US 2021/0217978 A1
(43) Pub. Date: Jul. 15, 2021

(54) TRANSISTOR ARRAY

(71) Applicant: Flexenable Limited, Cambridge (GB)

(72) Inventors: Josephine Socratous, Cambridge (GB); Herve Vandekerchove, Cambridge (GB)

(21) Appl. No.: 15/734,119

(22) PCT Filed: May 31, 2019
(86) PCT No.: PCT/EP2019/064220

§ 371 Date: Dec. 1, 2020

(30) Foreign Application Priority Data
Jun. 1, 2018 (GB) 1809031.6

(51) Int. Cl. H01L 51/10; H01L 27/28; H01L 51/05; H01L 51/00

(52) U.S. Cl. CPC H01L 51/105; H01L 51/0017; H01L 51/0541; H01L 27/28

(57) ABSTRACT

A technique of producing a device comprising a stack of layers defining an array of transistors and including one or more electrically conductive interlayer connections, wherein the method comprises: forming a source-drain conductor pattern defining an array of source conductors each providing an addressing line for a respective set of transistors of the transistor array, and an array of drain conductors each associated with a respective transistor of the transistor array; wherein forming said source-drain conductor pattern comprises forming a first conductor subpattern and thereafter forming a second conductor subpattern, wherein said first conductor subpattern provides the conductive surface of the source-drain conductor pattern in one or more interconnect regions where electrically conductive interlayer connections are to be formed to the source-drain conductor pattern, and the second conductor subpattern provides the conductive surface of the source-drain conductor pattern at least in the regions where the source and drain conductors are in closest proximity.

Transistor arrays may be defined by a stack of layers comprising conductor, semiconductor and insulator layers.

One important part of the stack is the source-drain conductor pattern that defines the source and drain conductors of the transistor array, and the inventors for the present application have carried out research into: (i) improving the transfer of charge carriers between the semiconductor channel and source/drain conductors and (ii) improving conductive connections between this source-drain conductor pattern and conductors at one or more other levels in the stack.

There is hereby provided a method of producing a device comprising a stack of layers defining an array of transistors and including one or more electrically conductive interlayer connections, wherein the method comprises: forming a source-drain conductor pattern defining an array of source conductors each providing an addressing line for a respective set of transistors of the transistor array, and an array of drain conductors each associated with a respective transistor of the transistor array; wherein forming said source-drain conductor pattern comprises forming a first conductor subpattern and thereafter forming a second conductor subpattern, wherein said first conductor subpattern provides the conductive surface of the source-drain conductor pattern in one or more interconnect regions where electrically conductive interlayer connections are to be formed to the source-drain conductor pattern, and the second conductor subpattern provides the conductive surface of the source-drain conductor pattern at least in the regions where the source and drain conductors are in closest proximity.

According to one embodiment, the method further comprises: forming said first conductor subpattern in regions substantially limited to said one or more interconnect regions and a peripheral region around each of said one or more interconnect regions; and said second conductor subpattern overlaps said first conductor subpattern in said peripheral regions.

According to one embodiment, the method further comprises: forming one or more layers over said source-drain conductor pattern, and thereafter forming via-holes in said one or more interconnect regions using a plasma generated from a gas comprising oxygen, and depositing conductor material in the interconnect regions; wherein the material of the first conductor subpattern exhibits less reduction in conductivity than the material of the second conductor subpattern under the conditions in which the via-holes are formed.

According to one embodiment, the material of the first conductor pattern exhibits substantially no reduction in conductivity upon exposure to said plasma.

According to one embodiment, the method further comprises forming a layer of semiconductor channel material over the source-drain conductor pattern to provide semiconductor channels for the array of transistors, and patterning the layer of organic semiconductor channel material using a plasma generated from a gas substantially excluding oxygen.

According to one embodiment, the plasma is generated from a gas consisting essentially of one or more noble gases.

According to one embodiment, the method further comprises: forming one or more layers over said source-drain conductor pattern; thereafter forming via-holes in said one or more interconnect regions; forming an upper conductor pattern over said one or more layers which upper conductor pattern contacts the first conductor subpattern through the via holes in said one or more interconnect regions; and wherein the contact between the upper conductor pattern and the first conductor sub-pattern is contact between different conductor materials.

There is also hereby provided a method, comprising: using a plasma generated from a gas substantially excluding oxygen to pattern a layer of an organic semiconductor channel material providing semiconductor channels in a stack of layers defining a transistor array.

According to one embodiment, the plasma is generated from a gas consisting substantially of one or more noble gases.

There is also hereby provided a device comprising a stack of layers defining an array of transistors and including one or more electrically conductive interlayer connections, wherein the device comprises: a source-drain conductor pattern defining an array of source conductors each providing an addressing line for a respective set of transistors of the transistor array, and an array of drain conductors each associated with a respective transistor of the transistor array; wherein said source-drain conductor pattern comprises a first conductor subpattern and a second conductor subpattern over the first conductor subpattern, wherein said first conductor subpattern provides the conductive surface of the source-drain conductor pattern in one or more interconnect regions where electrically conductive interlayer connections are to be formed to the source-drain conductor pattern and the second conductor subpattern provides the conductive surface of the source-drain conductor pattern at least in the regions where the source and drain conductors are in closest proximity.

According to one embodiment, said first conductor subpattern is formed in regions substantially limited to said one or more interconnect regions and a peripheral region around each of said one or more interconnect regions; and said second conductor subpattern overlaps said first conductor subpattern in said peripheral regions.

According to one embodiment, the device further comprises: one or more layers formed over said source-drain conductor pattern; and a further conductor pattern in contact with said source-drain conductor pattern in said one or more interconnect regions via via-holes; wherein the material of the first conductor subpattern is less easily oxidisable than the material of the second conductor subpattern in a reactive oxygen atmosphere.

According to one embodiment, the device further comprises: one or more layers formed over said source-drain conductor pattern; and an upper conductor pattern in contact with the first conductor subpattern in said one or more interconnect regions through via holes; and wherein the contact between the upper conductor pattern and the first conductor sub-pattern is contact between different conductor materials.

Embodiments of the present invention are described in detail below, by way of example only, with reference to the accompanying drawings, in which:

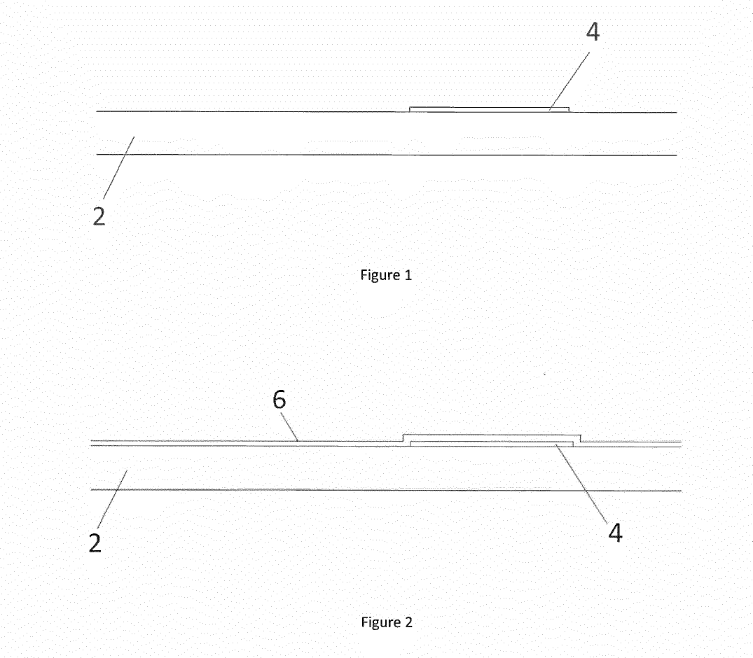

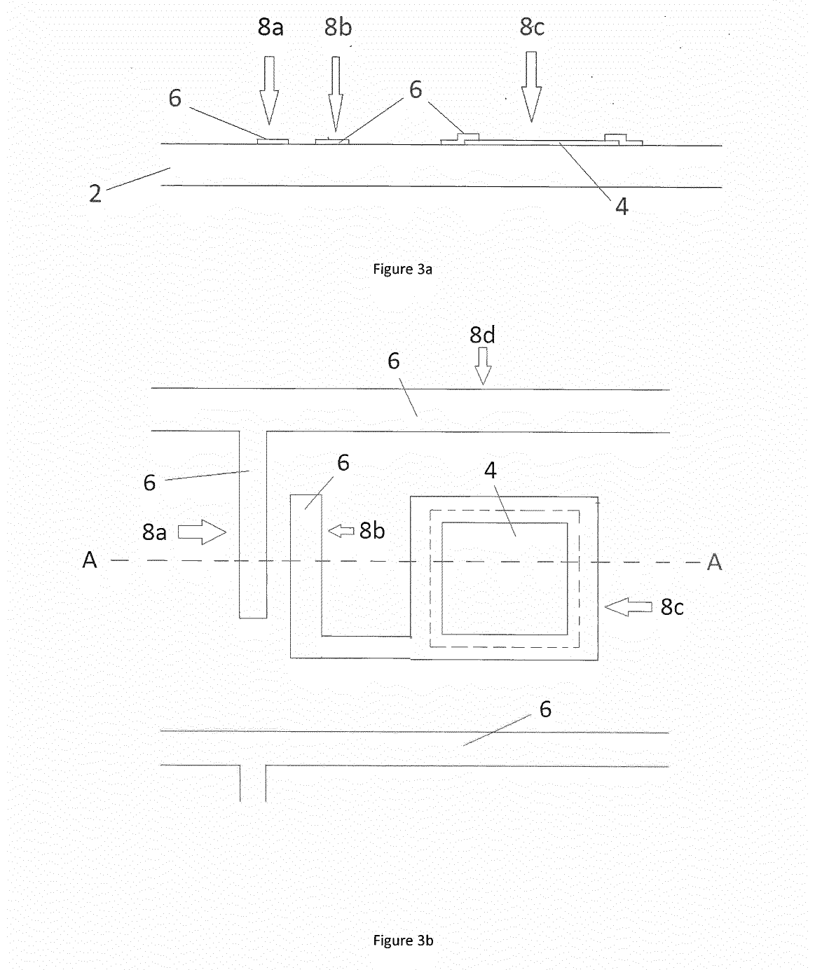

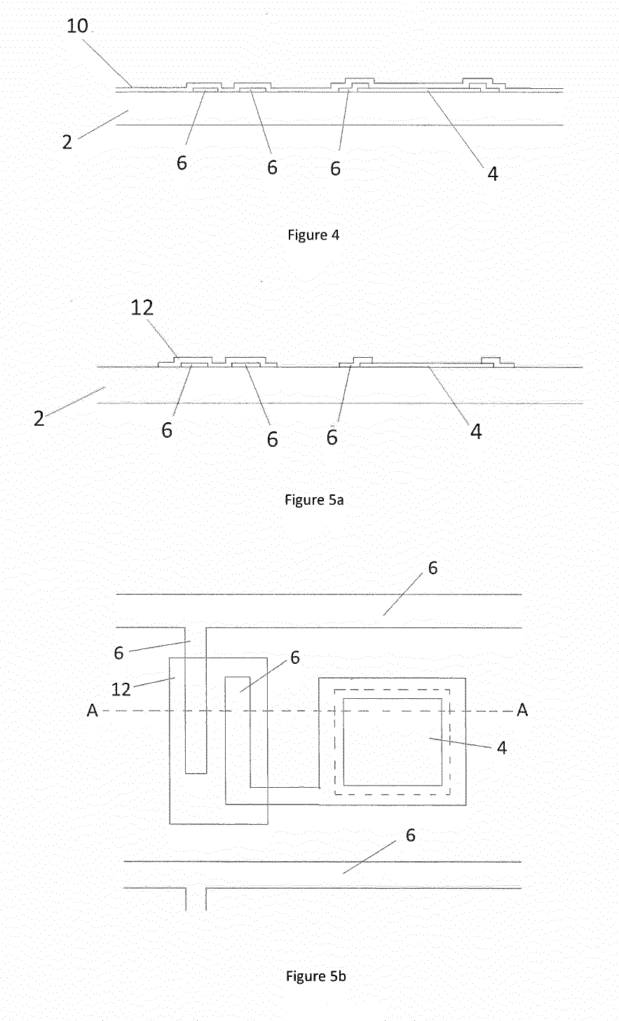

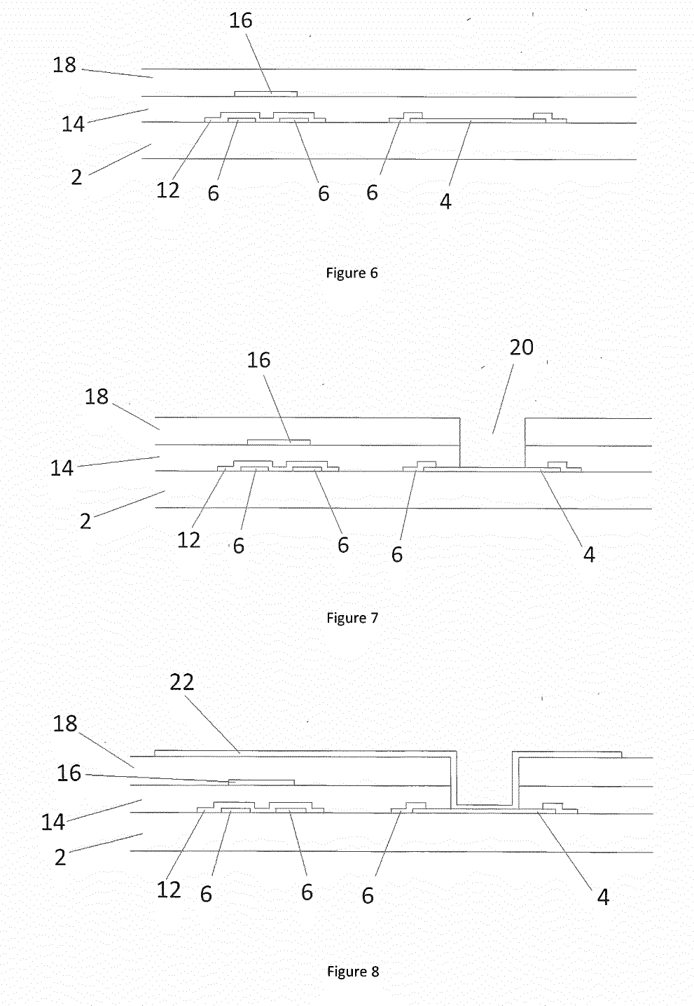

FIGS. 1 to 8 illustrate a process flow of an example embodiment of a technique according to the present invention, in which FIGS. 3b and 5b are cross-sections along the dashed lines A-A in FIGS. 3a and 5a, respectively.

For conciseness and clarity, the drawings focus on a single transistor region/single pixel in a thin film transistor (TFT)/multi-pixel array. The product device will typically comprise a very large number of such transistor regions/pixels.

The embodiments described below are for the example of top-gate transistor arrays, but the techniques are also applicable to other types of transistor arrays such as bottom-gate transistor arrays.

For the purposes of this document, the term “source conductor” refers to a conductor in electrical series between a driver chip terminal and the semiconductor channel, and the term “drain conductor” refers to a conductor in electrical series with the driver chip terminal via the semiconductor channel.

The semiconductor channel material may comprise one or more organic semiconductor materials (such as e.g. organic polymer semiconductors), and/or one or more inorganic semiconductor materials.

The embodiments described below use a silver alloy for a primary part of the source-drain conductor pattern. The relatively high work-function of the silver alloy is well-suited to the particular semiconductor channel material used in the research work carried out by the inventors, but other conductor materials (including also conductor materials with relatively low work functions) may be better suited to different semiconductor channel materials.

The embodiments described below use a conductive metal oxide (indium-tin-oxide (ITO)) for a secondary part of the source-drain conductor pattern, which conductive metal oxide has a sufficiently low relative etch rate for both the etchant used to pattern the layer of the particular semiconductor channel material used in the research work carried out by the inventors, and the etchant used to pattern the silver alloy layer discussed below. Other conductor materials may be used, and other conductor materials may be more suitable for use in combination with other semiconductor channel materials and/or other primary source-drain conductor materials.

A first step involves coating the working surface of a substrate 2 with ITO by a vapour deposition process. In this example, the substrate comprises an organic polymer support film (self-supporting plastic film), a patterned conductor layer providing light-shielding functionality in the product device, and an insulating, planarization layer at the surface.

The ITO coating is patterned by photolithography and etching (using e.g. oxalic acid or hydrochloric acid (HCl)). In this example, patterning of the ITO involves forming an ITO subpattern comprising islands 4 of ITO, each island 4 occupying the whole of a respective interconnect region and a peripheral region around the interconnect region. The accompanying drawings show the example of forming an island 4 of ITO in and around a region where an electrically conductive interlayer connection is to be created between a pixel conductor 22 at a higher level and a drain conductor.

After this ITO patterning, a layer 6 of silver alloy (e.g. silver alloy comprising 0.5% indium) is formed by vapour-deposition over the workpiece, including over the ITO islands 4. The deposition of the silver alloy layer 6 may be preceded by the deposition of one or more layers, such as one or more conductor layers that function to improve the adhesion of the silver alloy to the workpiece, to create a stack of sub-layers which are then patterned together. Hereafter, the term “silver alloy layer” is used to mean a single layer or a stack of two or more layers having a silver alloy at the upper surface. The silver alloy layer 6 is then patterned by photolithography and etching (using e.g. a mixture of phosphoric acid, acetic acid and nitric acid). The ITO subpattern 4 exhibits a relatively low etch rate with the etchant used to pattern the silver alloy layer.

The resulting source-drain conductor pattern (comprising the silver alloy subpattern 6 and the ITO subpattern 4) define at least (i) an array of source conductors each associated with a respective column of transistors and extending beyond an edge of the array for connection to a respective terminal of a driver chip (not shown), and (ii) an array of drain conductors, each drain conductor associated with a respective transistor. Each source conductor includes an addressing line 8d that extends beyond an edge of the array for connection to a respective terminal of driver chip, and one or more source conductor fingers 8a for each transistor, which conductor fingers 8a branch off from the addressing line 8d. The source conductor fingers 8a are the portions of the source conductor in closest proximity to the drain conductors. The drain conductor includes one or more drain conductor fingers 8b which extend in parallel to the source conductor fingers 8a (e.g. interdigitated with the source conductor fingers 8a), and which are the parts of the drain conductor in closest proximity to the source conductor. Each drain conductor also includes a drain pad 8c, defined by the ITO and silver alloy subpatterns 4, 6. The drain pad 8c is connected to the drain conductor finger(s) 8b within the silver alloy subpattern 6.

The silver alloy subpattern 6 overlaps the ITO subpattern 4 in the peripheral regions around the interconnect regions to make electrical contact with the ITO subpattern 4. Good alignment of the silver alloy subpattern 6 with the ITO subpattern 4 is achieved by using the same alignment marks (not shown) for fixing the position of the masks used for patterning the photoresists in the processes of patterning the ITO and silver alloy layers. For example, the alignment marks may be defined by the above-mentioned light-shielding conductor layer forming part of the substrate.

A film of a solution of the semiconductor channel material (or a precursor thereto) is deposited (by e.g. spin coating) over the workpiece. This may be preceded by the formation on the surface of the silver alloy subpattern 6 of one or more layers that improve charge transfer between the silver alloy subpattern 6 and the semiconductor channel material, such as e.g. a self-assembled monolayer of a suitable organic material.

After drying etc., the resulting layer of semiconductor channel material 10 is subjected to patterning to create an array of isolated islands 12 of semiconductor channel material, each island 12 providing the semiconductor channel for a respective transistor of the array. Patterning of layers of organic semiconductor channel material is conventionally performed using a plasma generated from a gas comprising oxygen, which involves chemical reaction of plasma species with exposed (unmasked) regions of the semiconductor channel material. The inventors for the present application have discovered that a plasma generated from a gas consisting essentially of argon (substantially excluding oxygen) can also be used to pattern an organic polymer semiconductor channel material, and that patterning using a 100% argon plasma can be better than patterning using an oxygen plasma, in terms of the performance of the product TFT array, for TFT arrays that comprise conductors below the semiconductor channel material (e.g. source-drain conductors) that are prone to oxidation. Without wishing to be bound by theory, the inventors for the present application attribute this improvement to the dominance of physical etching mechanisms (i.e. involving physical (non-chemical) interactions between the layer of organic polymer semiconductor channel material and the high-energy plasma species) with the 100% argon plasma.

Further processing of the workpiece continues with the formation, in sequence, of: a (e.g. organic polymer) gate dielectric layer (or stack of gate dielectric layers) 14; a patterned conductor layer (or stack of conductor layers) 16 defining at least an array of gate conductors, each associated with a respective row of transistors and each extending beyond an edge of the TFT array for electrical connection to a respective terminal of a driver chip; and an (e.g. organic polymer) insulator layer (or a stack of insulator layers) 18 over the patterned conductor layer. Each transistor is associated with a unique combination of gate and source conductors, whereby each pixel can be controlled independent of all other pixels.

A plasma generated from a gas comprising oxygen O₂ (e.g. a gas mixture of O₂ and sulphur hexafluoride SF₆) is used to create via holes 20 through the insulator layer(s) 18 and gate dielectric layer(s) 14 in regions where conductive interlayer connections are to be formed, including the regions where conductive interlayer connections are to be formed down to each drain conductor. As mentioned above, only the ITO subpattern 4 is located in the regions where such interlayer connections are to be formed, and the via-holes 20 expose parts of the ITO subpattern 4 without exposing the silver alloy sub-pattern 6.

A further conductor pattern is then formed over the workpiece, which further conductor pattern defines an array of pixel conductors 22 each connected to a respective drain conductor via a respective via-hole 20. In one embodiment, the further conductor pattern comprises ITO to provide highly transparent pixel conductors for e.g. a transmissive OLCD device using a backlight. In another embodiment, the further conductor pattern comprises a layer of a metal or metal alloy, such as molybdenum (Mo) or a silver alloy or a stack of metal and/or metal alloy layers, such as a stack comprising an aluminium (Al) sublayer sandwiched between two molybdenum (Mo) sublayers. The above-described improvement arising from the use of a ITO sub-pattern applies for both (i) the case (i) where the contact between the further conductor pattern and the ITO sub-pattern is contact between different conductor materials, and also (ii) the case (ii) where contact between the further conductor pattern and the ITO sub-pattern is contact between identical conductor materials.

Without wishing to be bound by theory, the ITO subpattern 4 is considered to improve the performance of the product device by better avoiding the formation of a non-conductor (metal oxide insulator) during the process of creating the via holes 20 using the oxygen plasma.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A method of producing a device comprising a stack of layers defining an array of transistors and including one or more electrically conductive interlayer connections, wherein the method comprises: forming a source-drain conductor pattern defining an array of source conductors each providing an addressing line for a respective set of transistors of the transistor array, and an array of drain conductors each associated with a respective transistor of the transistor array; wherein forming the source-drain conductor pattern comprises forming a first conductor subpattern and thereafter forming a second conductor subpattern, wherein the first conductor subpattern provides the conductive surface of the source-drain conductor pattern in one or more interconnect regions where electrically conductive interlayer connections are to be formed to the source-drain conductor pattern, and the second conductor subpattern provides the conductive surface of the source-drain conductor pattern at least in the regions where the source and drain conductors are in closest proximity.

2. The method according to claim 1, further comprising: forming the first conductor subpattern in regions substantially limited to the one or more interconnect regions and a peripheral region around each of the one or more interconnect regions; and the second conductor subpattern overlaps the first conductor subpattern in the peripheral regions.

3. The method according to claim 1, wherein the method further comprises: forming one or more layers over the source-drain conductor pattern, and thereafter forming via-holes in the one or more interconnect regions using a plasma generated from a gas comprising oxygen, and depositing conductor material in the interconnect regions; wherein the material of the first conductor subpattern exhibits less reduction in conductivity than the material of the second conductor subpattern under the conditions in which the via-holes are formed.

4. The method according to claim 3, wherein the material of the first conductor pattern exhibits substantially no reduction in conductivity upon exposure to the plasma.

5. The method according to claim 1, comprising forming a layer of semiconductor channel material over the source-drain conductor pattern to provide semiconductor channels for the array of transistors, and patterning the layer of organic semiconductor channel material using a plasma generated from a gas substantially excluding oxygen.

6. The method according to claim 5, wherein the plasma is generated from a gas consisting essentially of one or more noble gases.

7. The method according to claim 1, further comprising: forming one or more layers over the source-drain conductor pattern; thereafter forming via-holes in the one or more interconnect regions; forming an upper conductor pattern over the one or more layers which upper conductor pattern contacts the first conductor subpattern through the via holes in the one or more interconnect regions; and
wherein the contact between the upper conductor pattern and the first conductor sub-pattern is contact between different conductor materials.

8. A method, comprising: using a plasma generated from a gas substantially excluding oxygen to pattern a layer of an organic semiconductor channel material providing semiconductor channels in a stack of layers defining a transistor array.

9. The method according to claim 8, wherein the plasma is generated from a gas consisting substantially of one or more noble gases.

10. A device comprising a stack of layers defining an array of transistors and including one or more electrically conductive interlayer connections, wherein the device comprises: a source-drain conductor pattern defining an array of source conductors each providing an addressing line for a respective set of transistors of the transistor array, and an array of drain conductors each associated with a respective transistor of the transistor array; wherein the source-drain conductor pattern comprises a first conductor subpattern and a second conductor subpattern over the first conductor subpattern, wherein the first conductor subpattern provides the conductive surface of the source-drain conductor pattern in one or more interconnect regions where electrically conductive interlayer connections are to be formed to the source-drain conductor pattern, and the second conductor subpattern provides the conductive surface of the source-drain conductor pattern at least in the regions where the source and drain conductors are in closest proximity.

11. The device according to claim 10, wherein the first conductor subpattern is formed in regions substantially limited to the one or more interconnect regions and a peripheral region around each of the one or more interconnect regions; and the second conductor subpattern overlaps the first conductor subpattern in the peripheral regions.

12. The device according to claim 10, further comprising: one or more layers formed over the source-drain conductor pattern; and a further conductor pattern in contact with the source-drain conductor pattern in the one or more interconnect regions via via-holes; wherein the material of the first conductor subpattern is less easily oxidisable than the material of the second conductor subpattern in a reactive oxygen atmosphere.

13. The device according to claim 10, further comprising: one or more layers over the source-drain conductor pattern; and an upper conductor pattern in contact with the first conductor subpattern in the one or more interconnect regions through via holes; and wherein the contact between the upper conductor pattern and the first conductor sub-pattern is contact between different conductor materials.
